(19) United States
(12) Patent Application Publication
(10) Pub. No.: US 2025/0283945 A1
(43) Pub. Date: Sep. 11, 2025

(54) SYSTEMS AND METHODS FOR RAPID TESTING OF A WORKING ELECTRODE

(71) Applicant: TROJAN BATTERY COMPANY, LLC, Santa Fe Springs, CA (US)

(72) Inventors: Michael VERDE, Santa Fe Springs, CA (US); Shawn PENG, Santa Fe Springs, CA (US); Rex Holliday, Santa Fe Springs, CA (US)

(73) Assignee: TROJAN BATTERY COMPANY, LLC, Santa Fe Springs, CA (US)

(21) Appl. No.: 19/219,964

(22) Filed: May 27, 2025

Related U.S. Application Data
(63) Continuation-in-part of application No. 17/806,988, filed on Jun. 15, 2022, now Pat. No. 12,315,897.

(51) Int. Cl. G01R 31/379; G01R 31/36; G01R 31/3842; H01M 4/14; H01M 4/76; H01M 4/78; H01M 10/06

(52) U.S. Cl. CPC G01R 31/379; G01R 31/3646; G01R 31/3842; H01M 4/14; H01M 4/76; H01M 4/78; H01M 10/06

(57) ABSTRACT

A working electrode system includes a body; a conductive rod extending through two ends of the body and including a recess at one end, the recess being configured to retain an active material; a cap to retain the conductive rod to the body and being removably connected to a first end of the body; and a mask to seal and prevent the conductive rod from contacting an electrolyte liquid when the active material is submerged in the electrolyte liquid.

### CROSS REFERENCE TO RELATED APPLICATIONS

This application is a continuation-in-part, and claims the benefit, of U.S. patent application Ser. No. 17/806,988, filed Jun. 15, 2022, the entire contents of which is incorporated by reference for all purposes as if fully set forth herein.

### BACKGROUND

The disclosure relates generally to systems and methods for rapid testing of a working electrode and more particularly to a working electrode apparatus for rapidly testing lead-acid battery materials.

Battery testing is an expensive and time-consuming process to measure a plurality of different factors to determine which materials and/or substances improve the battery design.

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

In an embodiment, a system includes a body, a rod extending beyond a length of the body, a first cap at a first end of the body, and a second cap at a second end of the body. The first cap and the second cap are removably connected to the body. The system also includes a cup including an active material. The cup is located in the second cap. The system further includes a gasket between the cup and the body. The second cap exerting a force on the cup to press the cup against the gasket.

In further aspects, the first end of the body and the second end of the body include external threads, and the first cap and the second cap include internal threads. In further aspects, the first cap and the second cap attach to the body via the external threads and the internal threads.

In further aspects, the cup includes a cavity, and the cavity is configured to hold the active material.

In further aspects, the cup is flat and the active material is adhered to a surface of the cup.

In further aspects, the system includes a spring. The spring exerts a force on a flange of the rod and the first cap to maintain contact between the rod and the cup when the first cap is coupled to the body.

In further aspects, the gasket creates a seal between the cup and the body.

In further aspects, the first cap, the second cap, and the body are an insulating plastic.

In further aspects, the rod is a highly conductive metal.

In further aspects, the cup is an active material current collector.

In another embodiment, a rapid testing system includes a system including a body, a rod extending beyond a length of the body, a first cap at a first end of the body, and a second cap at a second end of the body. The first cap and the second cap are removably connected to the body. The system also includes a cup including an active material. The cup is located in the second cap. The system further includes a gasket between the cup and the body. The second cap exerting a force on the cup to press the cup against the gasket. The rapid testing system further includes a reference electrode, a counter electrode, and a container including an electrolyte liquid. The system, the reference electrode, and the counter electrode are at least partially submerged in the electrolyte liquid.

In further aspects, the rapid testing system includes a signal generator electrically coupled to the system, the reference electrode, and the counter electrode via wires.

In further aspects, the rapid testing system includes an ammeter arranged between the signal generator and the counter electrode, the ammeter being configured to measure and monitor a current.

In further aspects, the rapid testing system includes a voltmeter arranged between the signal generator and the reference electrode, the voltmeter being configured to measure and monitor a voltage.

In another embodiment, a rapid testing system includes a working electrode including a body, a rod extending beyond a length of the body, a cup including an active material. The cup being removably in contact with the rod. The rapid testing system also includes a gasket between the cup and the body, a reference electrode, and a counter electrode. The working electrode, the reference electrode, and the counter electrode are partially submerged in an electrolyte liquid. The rapid testing system also includes a signal generator electrically coupled to the working electrode, the reference electrode, and the reference electrode to generate a signal and measure characteristics of the active material.

In further aspects, the rapid testing system includes a computing device communicatively coupled to the signal generator. The computing device is configured to receive measured characteristics of the active material and display on a user interface of the computing device.

In further aspects, the rapid testing system includes a first cap at a first end of the body and a second cap at a second end of the body. The first cap and the second cap are removably connected to the body. The second cap includes a hole and exerts a force on the cup to press the cup against the gasket, creating a seal between the body and the cup.

In further aspects, the first end of the body and the second end of the body include external threads. In further aspects, the first cap and the second cap include internal threads. In further aspects, the first cap and the second cap attach to the body via the external threads and the internal threads.

In further aspects, the rapid testing system a spring, wherein the spring exerts a force on a flange of the rod and the first cap to maintain contact between the rod and the cup when the first cap is coupled to the body.

In further aspects, the cup includes a cavity, and the cavity is configured to hold the active material.

In further aspects, the cup is flat and the active material is adhered to a surface of the cup.

In an embodiment, a working electrode system includes a body; a conductive rod extending through two ends of the body and including a recess at one end, the recess being configured to retain an active material; a cap to retain the conductive rod to the body and being removably connected to a first end of the body; and a mask to seal and prevent the conductive rod from contacting an electrolyte liquid when the active material is submerged in the electrolyte liquid.

In an aspect, The system of claim 1, further comprising a cup removable from the system and including a cavity, wherein the cup is configured to contact the conductive rod, and the cavity is configured to contain the active material.

In an aspect, the first end of the body and a second end of the body include external threads, and the cap is attached to the first end of the body via the external threads.

In an aspect, the system of claim 1, wherein the conductive rod includes a flange between the cap and the body.

The system can further include a nut removably connected to the second end of the body.

The system can further include a gasket between the cap and the body, wherein the gasket creates a seal between the cap and the body.

The system can further include a gasket that provides a seal between the cap and the flange of the conductive rod.

In an aspect, the nut is configured to retain the working electrode through a side of a container.

In another embodiment, a rapid testing system includes the working electrode system; a reference electrode; a counter electrode; a container including an electrolyte liquid, the system of claim 1, the reference electrode, and the counter electrode being at least partially submerged in the electrolyte liquid.

In an aspect, the counter electrode is uniformly distributed across from the active material.

In another embodiment, a rapid testing system includes a working electrode including: a body; a conductive rod extending beyond a length of the body; a cup configured to hold an active material, the cup being removably in contact with the conductive rod; and a mask to seal and prevent the conductive rod from coming into contact with the electrolyte; a reference electrode; and a counter electrode, wherein the working electrode, the reference electrode, and the counter electrode are partially submerged in an electrolyte liquid; and a signal generator is electrically coupled to the working electrode, the counter electrode, and the reference electrode to generate a signal and measure characteristics of the active material.

The rapid testing system further includes a cap removably connected to the body, wherein the cap includes a hole exposing the cup and exerting a force on the conductive rod to press the conductive rod against a gasket, creating a seal between the conductive rod and the cap.

In an aspect, a first end of the body and a second end of the body include external threads, the cap includes internal threads, and the cap attaches to the first end of the body via the external threads and the internal threads.

The system can further include a nut configured to screw onto external thread of the second end of the body to retain the working electrode to a side of a container containing the electrolyte liquid.

In an aspect, the mask is a sealing tape configured to expose a portion of the active material held in the cup.

Further areas of applicability of the present disclosure will become apparent from the detailed description, the claims, and the drawings. The detailed description and specific examples are intended for purposes of illustration only and are not intended to limit the scope of the disclosure.

### BRIEF DESCRIPTION OF THE DRAWINGS

The features and advantages of the present disclosures will be more fully disclosed in, or rendered obvious by, the following detailed descriptions of example embodiments. The detailed descriptions of the example embodiments are to be considered together with the accompanying drawings wherein like numbers refer to like parts and further wherein:

FIG. 1 is an example diagram illustrating a rapid testing system setup for a working electrode in accordance with some embodiments;

FIG. 2 is an example diagram illustrating a working electrode of the rapid testing system setup of FIG. 1 in accordance with some embodiments;

FIG. 3 is a cross section of the example diagram illustrating the working electrode of the rapid testing system setup of FIG. 1 in accordance with some embodiments;

FIG. 4 is an example diagram illustrating a top cap of the working electrode of FIGS. 2 and 3 in accordance with some embodiments;

FIG. 5 is an example diagram illustrating a bottom cap of the working electrode of FIGS. 2 and 3 in accordance with some embodiments;

FIG. 6 is a graphical depiction of half-cell formation voltage of lead-acid positive and negative working electrodes in accordance with some embodiments;

FIG. 7 is a graphical depiction of full-cell discharge capacity of lead-acid positive and negative working electrodes in accordance with some embodiments;

FIG. 8 is a graphical depiction of half-cell cyclic voltammetry of a negative electrode in accordance with some embodiments;

FIG. 9 is a graphical depiction of half-cell cyclic voltammetry of a positive electrode in accordance with some embodiments; and

FIG. 10 is a graphical depiction of electrochemical impedance (EIS) spectra of a working electrode in accordance with some embodiments.

FIG. 11 is a perspective view of rapid testing system according to some embodiments.

FIG. 12 is an exploded view of the rapid testing system shown in FIG. 11.

FIG. 13 is a cross section of a working electrode according to some embodiments,

FIG. 14 is a close-up view of a bottom of the working electrode shown in FIG. 13.

FIG. 15A and FIG. 15B are views of a cup according to some embodiments.

FIG. 16A and FIG. 16 B are views of another cup according to some embodiments.

In the drawings, reference numbers may be reused to identify similar and/or identical elements.

### DETAILED DESCRIPTION

The description of the preferred embodiments is intended to be read in connection with the accompanying drawings, which are to be considered part of the entire written description of these disclosures. While the present disclosure is susceptible to various modifications and alternative forms, specific embodiments are shown by way of example in the drawings and will be described in detail herein. The objectives and advantages of the claimed subject matter will become more apparent from the following detailed description of these exemplary embodiments in connection with the accompanying drawings.

It should be understood, however, that the present disclosure is not intended to be limited to the particular forms disclosed. Rather, the present disclosure covers all modifications, equivalents, and alternatives that fall within the spirit and scope of these exemplary embodiments. The terms “couple,” “coupled,” “operatively coupled,” “connected,” “operatively connected,” and the like should be broadly understood to refer to connecting devices or components together either mechanically, electrically, wired, wirelessly, or otherwise, such that the connection allows the pertinent devices or components to operate (e.g., communicate) with each other as intended by virtue of that relationship.

A rapid testing system setup provides a method of quickly testing a plurality of active materials or pastes using a working electrode configuration that easily replaces an active material with another active material. The rapid testing system is an apparatus including a working electrode, which can be used in a three-electrode system to test the properties of each active material of the plurality of active materials to identify the active material that is best used in a lead-acid battery, for example. For example, the rapid testing system may be capable of testing both positive active-materials and negative active-materials. The rapid testing system includes a cup that is attached to a body of the working electrode by a threaded, bottom cap. To replace and test multiple active materials, a plurality of cups can hold one of the active materials of the plurality of active materials. Each cup can be replaced in the rapid testing system by removing the bottom cap, removing a present cup, and adding in another cup with a different active material. In this way, the same working electrode can be used to test a different active material that is easily added to the working electrode and used within the same three-electrode system.

The working electrode is specially designed for the rapid and fundamental analysis of a variety of active materials and more particularly to the electrochemical performance of the multiple different active materials used in lead-acid battery or other applications. The presently described designs are particularly directed towards, but not limited to, the optimization of lead-acid battery materials and formulae. The development and testing of battery materials is a costly endeavor, specifically regarding the time and resources (equipment, material, personnel, etc.) required. A robust design of experiment aimed to optimize three to four different conditions may require the construction of tens or hundreds of large batteries, and each battery is potentially comprised of tens of kilograms of lead (in the case of lead-acid batteries). Assembling these batteries may require a number of personnel, high-current/voltage testing platforms, and monitoring over the course of months.

The disclosure is about a core battery system necessary to optimize active materials, or specifically regarding lead-acid batteries, and pastes, into a simplified working electrode. The working electrode mimics the performance of paste within a single electrode of a full-cell battery. Moreover, the working electrode of the rapid testing system requires less than one gram of paste or active material, enabling fewer personnel to more easily synthesize, assemble, and test a large array of active materials and conditions. Because of the small and controlled size, the working electrode also allows for the use of smaller and less expensive equipment, as well as much faster testing. In addition, by focusing the analysis on a single electrode, the working electrode can provide a more detailed and fundamental understanding of the reactions occurring.

The rapid testing system includes a working electrode design meant for rapid testing and screening of electrochemically active materials and/or additives included in a battery electrode. The rapid testing system includes an electrically insulating body and two insulating endcaps: a top cap and a bottom cap. A bottom section includes a cup that holds active material within a cavity, and a gasket. The bottom cup can be composed of current collector material suitable for the active material attached, for example, lead, aluminum, copper, etc. The bottom cup dimensions can vary such that the volume is zero, meaning the active material is affixed to a flat current collector substrate or include a cavity for holding the active material. In various implementations, the cup can have certain dimensions for certain active materials, such as pastes including positive active material (PAM) and negative active material (NAM) present in lead-acid batteries.

The gasket can be placed on top of the bottom cup so that when the bottom cap is coupled to or threaded onto the body, a seal is formed between the bottom cup, the body, and the bottom cap. A hole is inside the bottom through which a highly conductive rod can be placed or inserted. The rod is in contact with a back of the cup opposite to where active material is adhered within a chamber that is sealed by the gasket. The top cap couples to, via threads on the top cap and the body, the other side of the body. When the top cap is coupled to the body, the rod is pushed towards the bottom cap. In other words, the top cap exerts a downward force on a spring located between the top cap and the flange of the rod to maintain strong and controlled contact between the rod and the cup.

The bottom portion of the working electrode is submerged in electrolyte. The top portion, with rod exposed, is connected to the testing instrument via, for example, an alligator clip or other suitable connector. The working electrode is treated as a working electrode in a variety of electrode testing configurations, including, for example, a reference electrode and a counter electrode. While testing with small, cylindrical working electrodes is common in the field of electrochemistry, those electrodes are typically composed of a single, uniform body. In the presently described invention, the bottom cap is removable to replace the cup, and with it the active material, to easily and quickly test a plurality of active materials. That is, the prior art configurations include components that are fixed in place and cannot be separated from one another.

One of the key unique features of the rapid testing system is that the current collector of the cup is tailored to the active material of interest and can be easily swapped in and out of the working electrode. That is, the cup can be subject to standard active material processing conditions. The design and functionality of the cup enables the application, assembly, and testing of active material to much more closely mimic behavior in an actual battery environment. The ability to repeatedly remove and insert the cup from the rest of the working electrode at any point during testing also enables complimentary analysis to be easily performed, for example, using x-ray, electron, optical techniques etc. Overall, the rapid testing system provides faster testing, greater insight into material mechanisms, more accurate modeling of full-scale lead-acid battery systems, and larger testing arrays that can be more easily performed on a variety of cups including different active materials.

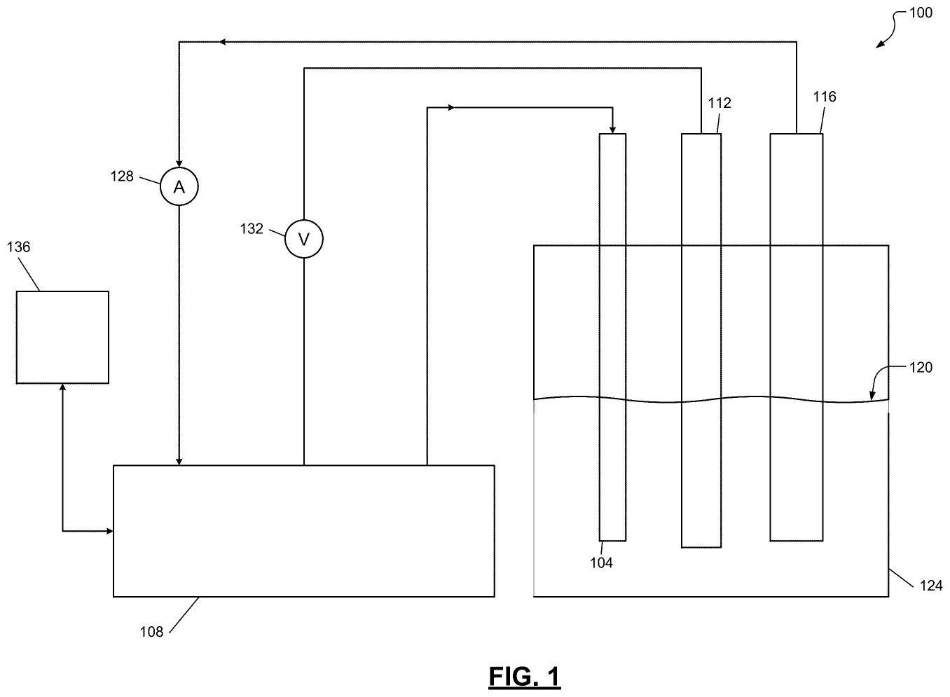

Referring now to FIG. 1, an example diagram illustrating a rapid testing system 100 setup for a working electrode 104 is shown. A signal generator 108 can be electrically coupled to the rapid testing system 100. In various implementations, the signal generator 108 can be a potentiostat, a voltage generator, galvanostat, impedance analyzer, etc. The rapid testing system 100 can include the working electrode 104, a reference electrode 112, and a counter electrode 116 partially submerged in an electrolyte substance 120, all of which are included in a container 124. Electrical wire connects the signal generator 108 to the working electrode 104, the reference electrode 112, and the counter electrode 116. An ammeter 128 can be included between the signal generator 108 and the counter electrode 116 to measure a current, and a voltmeter 132 can be between the signal generator 108 and the reference electrode 112 to measure a voltage. In various implementations, the ammeter 128 and the voltmeter 132 can be connected to a computing device 136 including a memory and at least one processor for analyzing and storing measurement data for each of the different cups and active material being tested and measured. The computing device 136 can also include a display configured to display measurements of the active material. As described above, the working electrode 104 includes a replaceable cup with active material for testing and measurement within the rapid testing system.

Referring to FIG. 2, an example diagram illustrating the working electrode 104 of the rapid testing system 100 setup of FIG. 1 is shown. As previously described, the working electrode 104 includes a body 204, a rod 208, a top cap 212, and a bottom cap 216. The body 204, the top cap 212, and the bottom cap 216 can be made of an insulating material and the rod 208 can be made of a highly conductive material.

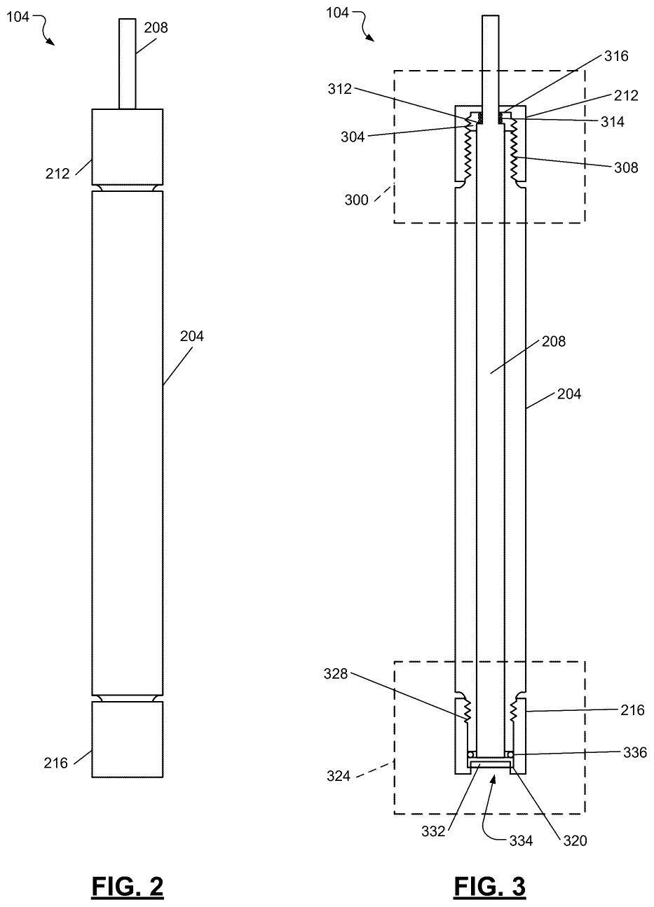

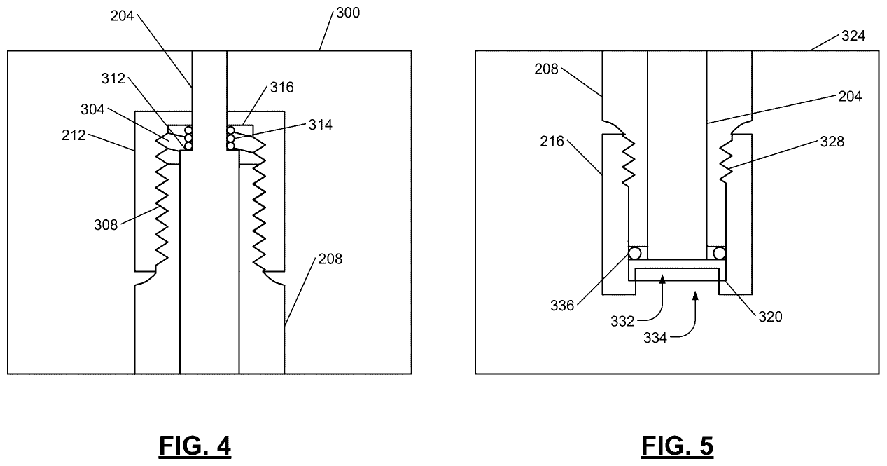

Referring to FIG. 3, a cross section of the example diagram illustrating the working electrode 104 of the rapid testing system 100 setup of FIG. 1 is shown. A top cap section 300 depicts a cavity 304 of the top cap 212 and illustrates external threads 308 of the body 204 coupled to the top cap 212. In various implementations, a flange 312 of the rod 208 is being held or pressed down by a spring 314. The spring 314 may be included between the flange 312 of the rod 208 and a top cavity portion 316 of the top cap 212. The spring 314 exerts a downward force against the flange 312 and an upward force against the top cap 212 to ensure contact between the rod 208 and a cup 320 shown in a bottom cap section 324. In further implementations, the flange 312 may be in contact with the top cavity portion 316 of the top cap 212. In such an implementation, the top cavity portion 316 exerts a downward force on the rod 208 to ensure contact between the rod 208 and the cup 320 shown in the bottom cap section 324. The other end of the body 204 is shown in the bottom cap section 324 and also includes external threads 328 (the bottom cap 216 and top cap 212 including internal threads) to attach to the bottom cap 216.

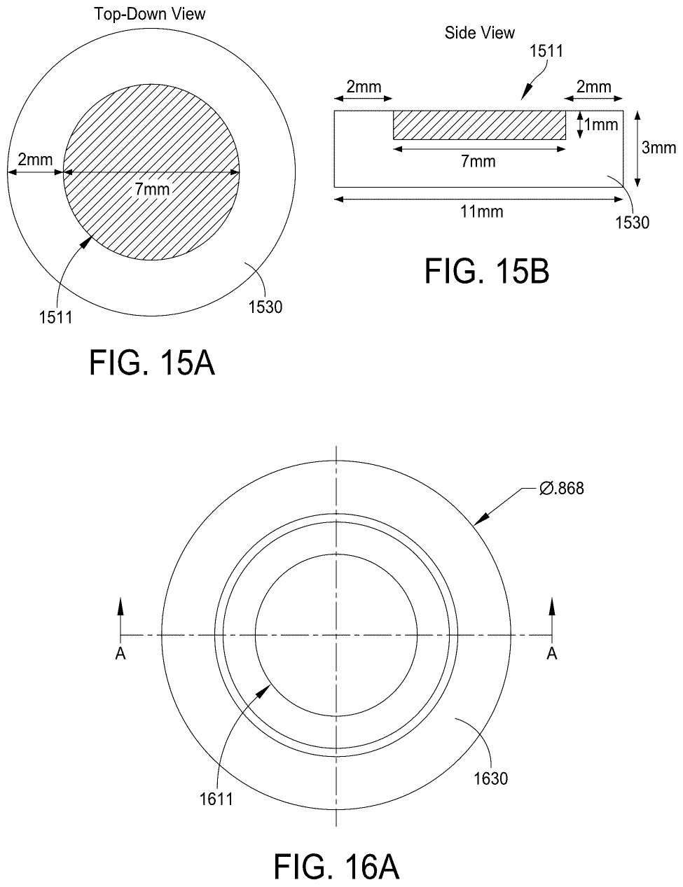

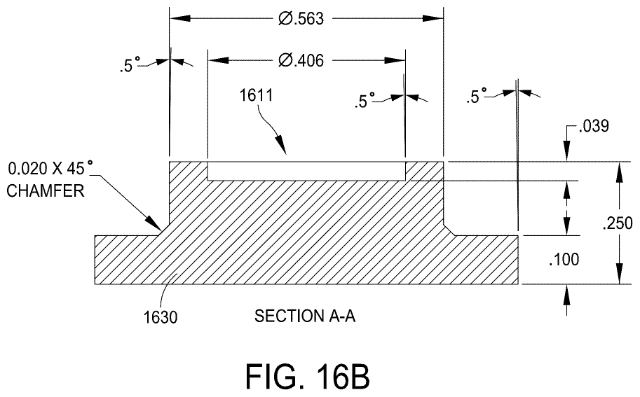

The cup 320 includes a cup cavity 332 that receives and holds active material or paste placed in the cup cavity 332 to test and measure. As discussed above, the cup 320 can be flat or include the cup cavity 332 based on the active material being tested. Further, the cup 320 can be comprised of or made from a current collector material based on the active material being tested and measured. In some embodiments, the cup 320 can be configured like the structures shown and described with respect to FIGS. 15 and 16. A gasket 336 is placed between the body 204 and the cup 320 creating a seal to protect the rod 208 from the electrolyte in which the bottom cap section 324 is placed for measurements. The gasket 336 can be a ring made from a silicone or other material that creates a liquid-proof seal between the body 204 and the cup 320. As also shown, the rod 208 is in continuous contact with the cup 320 as a result of the top cap 212 and the bottom cap 216 being screwed on to the body 204. The rod 208 exits a top of the top cap 212 to connect to an electrical wire or other electrical connection to receive signals and measure properties of the active material adhered to the cup 320. As also shown, the bottom cap 216 includes an opening 334 so that the electrolyte can reach the active material or paste placed in the cup cavity 332 for testing.

Referring to FIGS. 4 and 5, an example diagram illustrating the top cap 212 of the working electrode 104 and an example diagram illustrating the bottom cap 216 of the working electrode 104 are shown, respectively.

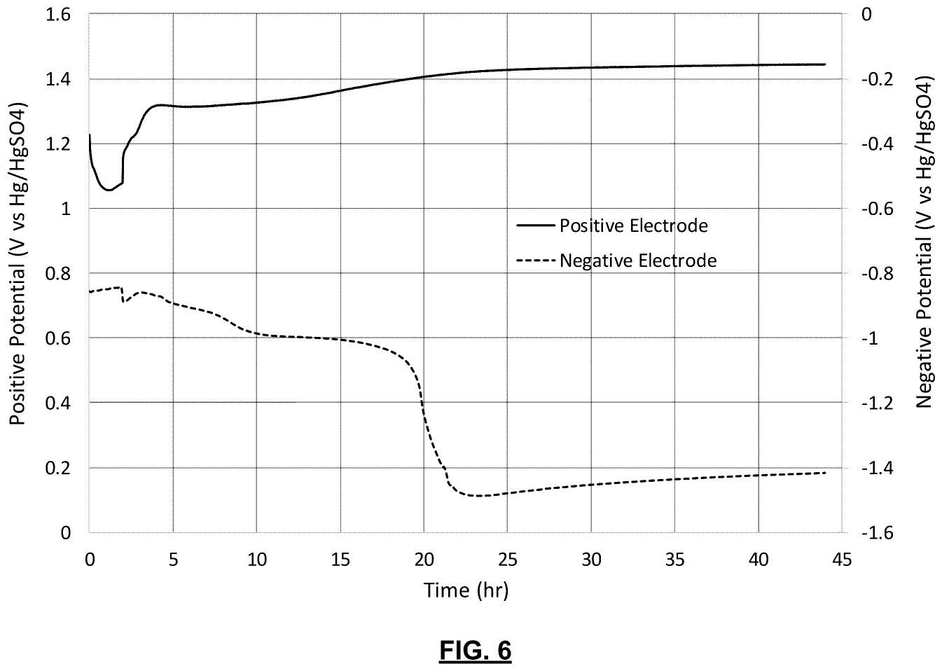

Generally, FIGS. 6-10 depict how the working electrode design presented above functions as an effective electrode to use in an array of electrochemical analyses. Referring to FIG. 6, a graphical depiction of half-cell formation voltage of lead-acid positive and negative working electrodes is shown. As shown in the graph, the measurements of the positive potential and negative potential for the corresponding electrode over time is depicted.

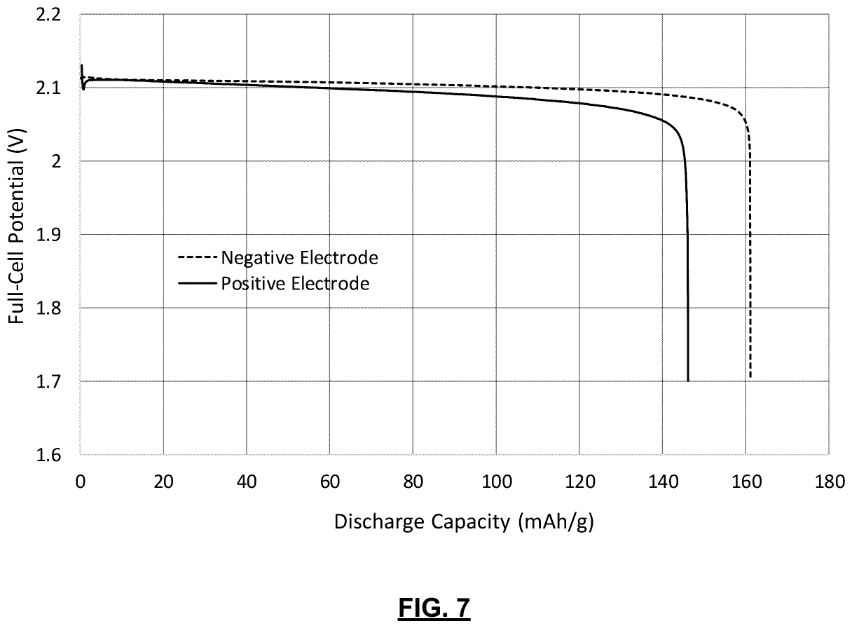

Referring to FIG. 7, a graphical depiction of full-cell discharge capacity of lead-acid positive and negative working electrodes is shown. As shown in the graph, the discharge capacity is depicted from the positive and negative electrodes.

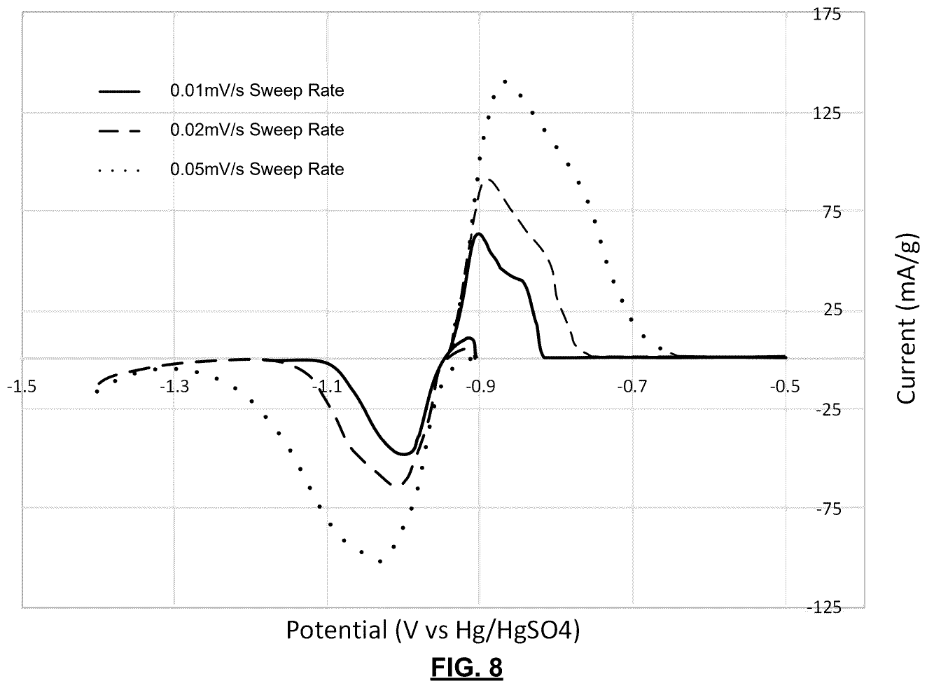

Referring to FIG. 8, a graphical depiction of half-cell cyclic voltammetry of a negative electrode is shown. As shown, in a lead-acid system, a negative electrode is swept at rates of 0.01 mV/s, 0.02 mV/s, and 0.05 mVs while measuring current as a function of voltage against a Hg/HgSO4 reference electrode.

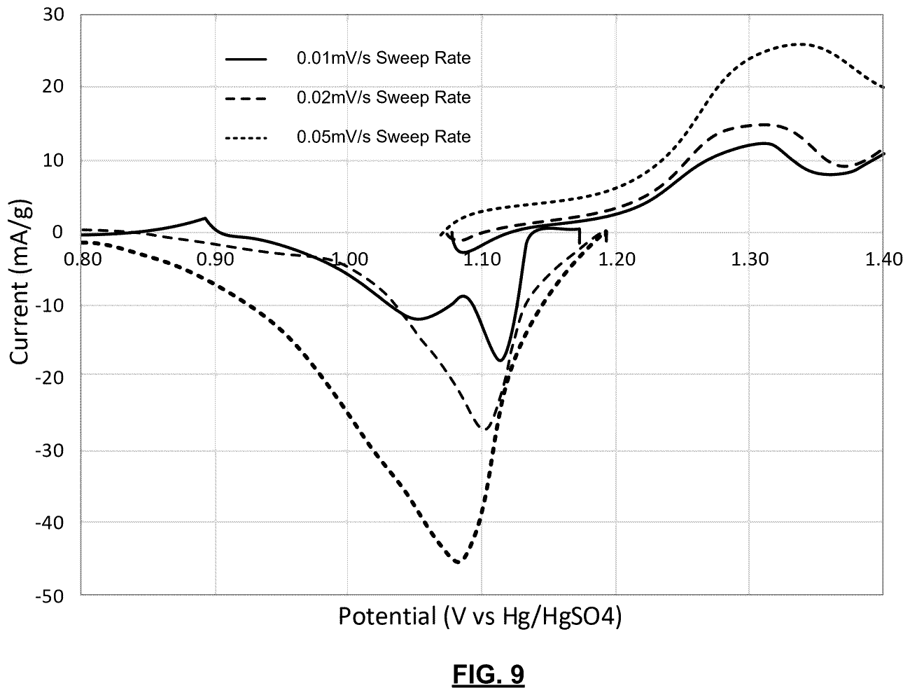

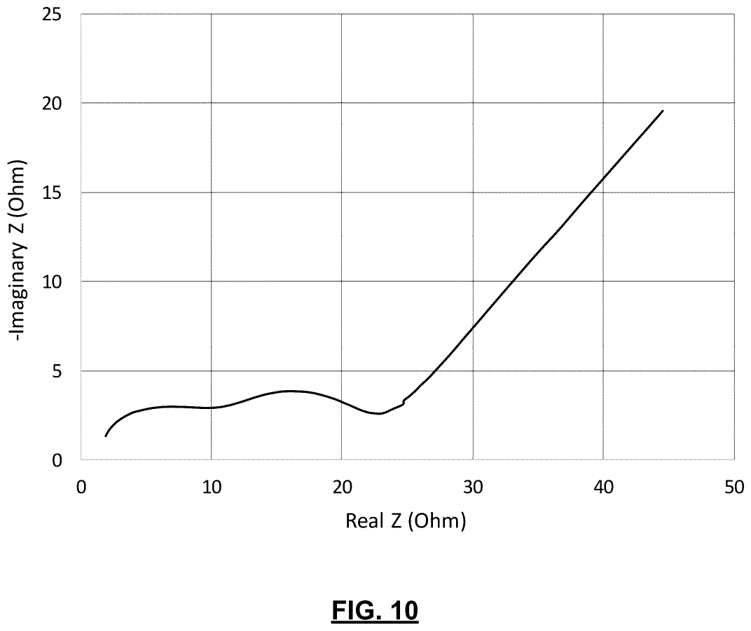

Referring to FIG. 9, a graphical depiction of half-cell cyclic voltammetry of a positive electrode is shown. As shown, in a lead-acid system, a positive electrode is swept at rates of 0.01 mV/s, 0.02 mV/s, and 0.05 mVs while measuring current as a function of voltage against a Hg/HgSO4 reference electrode.

Referring to FIG. 10, a graphical depiction of electrochemical impedance (EIS) spectra of a working electrode is shown.

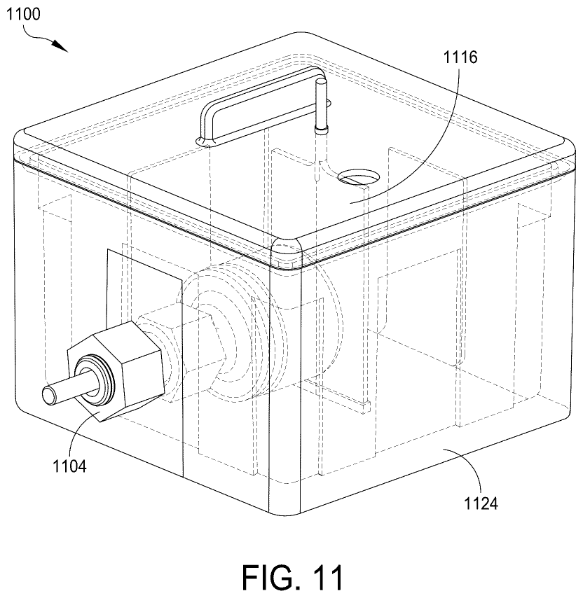

FIGS. 11 to 16 are used to describe a rapid testing system 1100 according to another embodiment of the present disclosure. The rapid testing system 1100 can include components like those shown and described with respect to FIG. 1, some of which are not shown or described for brevity. Referring to FIG. 11, the rapid testing system 1100 can include a working electrode 1104, a reference electrode (not shown), and a counter electrode 1116 at least partially submerged in an electrolyte substance (not shown), all of which are included in a container 1124. A signal generator, electrical wires connecting the electrodes 1104 and 1116 to the signal generator, voltage and current meters, and a computer device are not shown but can be provided and connected like components previously described. In this system 1100, the working electrode 1104 can be positioned in the electrolyte substance through a side of the container 1124 and across from the counter electrode 1116. The working electrode 1104 can include a replaceable rod and cup, combined to retain the active material for testing and measurement within the rapid testing system 1100.

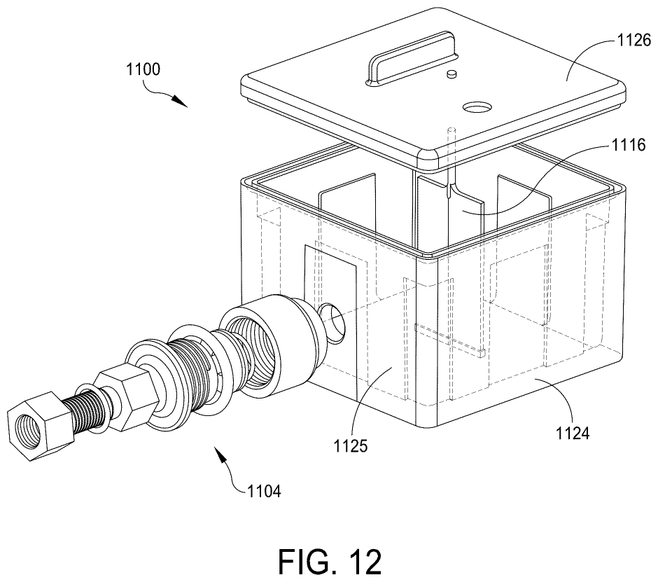

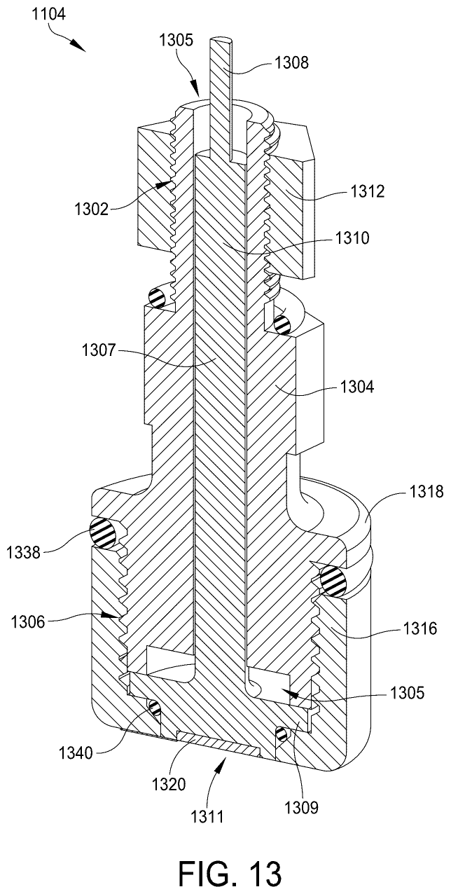

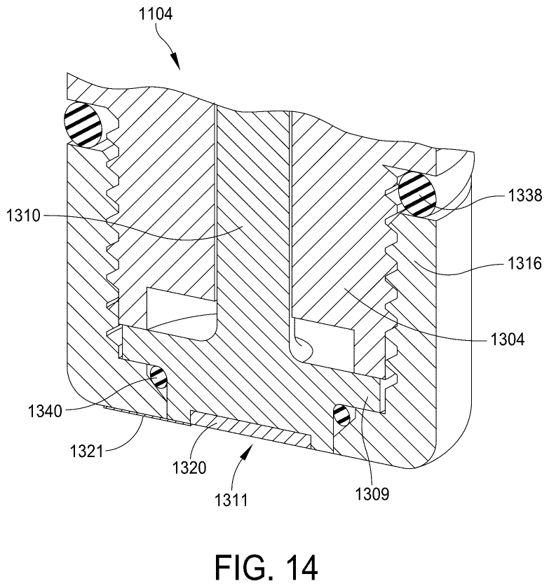

FIG. 12 shows an exploded view of the rapid testing system 1100 including the working electrode 1104, the counter electrode 1116, the container 1124, and a container lid 1126. This configuration allows for a smaller container with improved sealing. The sealing reduces waste, controls evaporation, and controls pH of the electrolyte substance. A more detailed description of the working electrode 1104 is provided with respect to FIGS. 13 and 14.

As shown in FIG. 12, the container 1124 is configured to contain the liquid electrolyte substance and receive the working electrode 1104 sealed through a side wall 1125 of the container 1124 to prevent leakage of the electrolyte substance. A bottom end of the working electrode 1104 protrudes into the container 1124 and is submerged in the electrolyte substance. As shown, for example, the container 1124 can be cubic shaped or at least include a flat side surface 1125 to which the working electrode 1104 can be sealed therethrough. The container lid 1124 can cover the container 1124 and include holes in which portions and/or connections to the counter electrode 1116 and reference electrode and sensors can pass through.

The counter electrode 1116 can be configured as a substantially planar structure with a plane of a major surface oriented in parallel with an active material retained in a recess of the working electrode 1104 or a cup attached to the working electrode 1104. The counter electrode 1116 can be sized and oriented such that it is uniformly distributed across from the active material at the bottom end of the working electrode 1104 providing a more uniform electric field.

FIG. 13 is a section view of the working electrode 1104. As shown, the working electrode 1104 can include a body 1304, a current collector 1310, a nut 1312, a bottom cap 1316, a cup 1320, and various gaskets or O-rings 1336, 1338, and 1340. The body 1304 can include a bore 1305 entirely through the body 1304 in which the currently collector 1310 can be inserted. The body 1304 can also include first external threads 1302 in which the nut 1312 can be screwed onto and second external threads 1306 in which the bottom cap 1316 can be screwed onto. In some embodiments, the body 1104 can also include a recess 1305 at a bottom end, to ensure even pressure is placed on a flange 1309 of the current collector 1310 and not compromise the structural stability of the active material 1320.

The current collector 1310 can include a cylindrical central portion 1307 with a round cross section that fits within the bore 1305 of the body 1304, a connection portion 1308 at one end with a diameter less than the central portion 1307 for connecting to a wire or connector and a bottom portion at another end of the central portion opposite from the connection portion 1308. The bottom portion of the current collector 1310 can include a flange 1309 that has a diameter greater than the central portion 1307. The diameter of the flange 1309 can be such that it is substantially the same as or less than the diameter of the bottom end of the body 1304. The bottom end of the current collector can also include a recess 1311 for placement of the active material 1320. In some embodiments, the current collector 1310 is made of lead. In some embodiments, the recess 1311 can be configured to receive a cup configured to retain the active material 1320.

The current collector 1310 can be inserted through the bottom end of the body 1304 and held in place by screwing the bottom cap 1316 on the second external threads 1306 of the body 1304 to provide a press fit of the flange 1309 to the body 1304 while compressing (i) the O-ring 1338 to a flange 1318 of the body 1304 and (ii) the O-ring 1340 to an underside of the flange 1309 of the current collector. Compressing these O-rings 1338 and 1340 provide seals to prevent egress of the electrolyte substance into the bottom end of the body 1304. In some embodiments, the current collector 1310 does include a recess and can instead be configured to contact a cup that is inserted and held in contact by the bottom cap 1316.

FIG. 14 is a close-up view of a bottom end of the working electrode 1104 showing a top of the flange 1309 of the current collector 1310 flush against the body 1304 when the bottom cap 1316 is screwed into place to compress the O-rings 1338 and 1340. This view also shows the recess 1311 of the current collector 1310 being cup shaped in which the active material 1320 can be placed. In some embodiments, the body 1304 and/or the cap 1316 are made of an electrically insulating material.

Active material 1320 for testing can be placed in the recess 1311 or a cup and can be masked off with a sealer or mask 1321 such as sealing tape or an adhesive spanning a portion of the recess 1311 to the bottom of the bottom cap 1316. That is, the mask 1321 can be configured to expose only a predefined portion of the active material 1320 in the recess 1311. This seals and prevents the current collector 1320 from contacting the electrolyte substance when the bottom end of the working electrode 1104 with the active material 1320 is submerged in the electrolyte substance. Thus, the active material 1320 is parallel to a bottom surface of the recess 1311 of the current collector 1310 and at a fixed position to the current collector 1310. This geometry makes it easier for gas bubbles to escape during testing, provides a uniform electrical field between the active material 1320 and the current collector 1310, and provides a stable mechanical interface between the active material 1320 and the current collector 1310.

The working electrode 1104 can fit from an inside of the container 1124 and through a hole in the side surface 1125 and held to the side surface 1125 by screwing the nut 1312 over the first external threads from the outside. Tightening the nut 1312 compresses the O-ring 1336 to provide a seal between the working electrode 1104 and the container 1124 to prevent leakage of the electrolyte substance that is inside the container 1124. This side-mounted orientation and geometry aligns the bottom of the recess 1311 with active material 1320 and current collector 1310 to be parallel to and a fixed distance from a major surface of the current collector 1116.

FIG. 15A is a top view and FIG. 15B a side cross section view of a cup 1530 according to an exemplary embodiment of the disclosure. These views show that the cup 1530 can be rounded or disk shaped and includes a rounded recess 1511 in which to retain active material 1520. Dimensions shown can be varied for the application and type of active material.

FIG. 16A is a top view and FIG. 16B a side cross section view of a cup 1630 along line A-A of FIG. 16A according to another exemplary embodiment of the disclosure. These views show that the cup 1630 can be rounded or disk shaped and include a rounded recess 1611 in which to retain active material 1620. As shown, this cup 1630 can include a stepped portion to adjust the location of the recess 1611 and the active material 1620 inserted therein. Dimensions shown can be varied for the application and type of active material.

In addition, the methods and system described herein can be at least partially embodied in the form of computer-implemented processes and apparatus for practicing those processes. The disclosed methods may also be at least partially embodied in the form of tangible, non-transitory machine-readable storage media encoded with computer program code. For example, the steps of the methods can be embodied in hardware, in executable instructions executed by a processor (e.g., software), or a combination of the two. The media may include, for example, RAMs, ROMs, CD-ROMs, DVD-ROMs, BD-ROMs, hard disk drives, flash memories, or any other non-transitory machine-readable storage medium. When the computer program code is loaded into and executed by a computer, the computer becomes an apparatus for practicing the method. The methods may also be at least partially embodied in the form of a computer into which computer program code is loaded or executed, such that, the computer becomes a special purpose computer for practicing the methods. When implemented on a general-purpose processor, the computer program code segments configure the processor to create specific logic circuits. The methods may alternatively be at least partially embodied in application specific integrated circuits for performing the methods.

The foregoing is provided for purposes of illustrating, explaining, and describing embodiments of these disclosures. Modifications and adaptations to these embodiments will be apparent to those skilled in the art and may be made without departing from the scope or spirit of these disclosures.

What is claimed is:

1. A working electrode system comprising:
a body;
a conductive rod extending through two ends of the body and including a recess at one end, the recess being configured to retain an active material;
a cap to retain the conductive rod to the body and being removably connected to a first end of the body; and
a mask to seal and prevent the conductive rod from contacting an electrolyte liquid when the active material is submerged in the electrolyte liquid.

2. The system of claim 1, wherein:
the first end of the body and a second end of the body include external threads, and
the cap is attached to the first end of the body via the external threads.

3. The system of claim 1, further comprising a cup removable from the system and including a cavity, wherein
the cup is configured to contact the conductive rod, and
the cavity is configured to contain the active material.

4. The system of claim 1, wherein the conductive rod includes a flange between the cap and the body.

5. The system of claim 2, further comprising a nut removably connected to the second end of the body.

6. The system of claim 1, further comprising a gasket between the cap and the body, wherein the gasket creates a seal between the cap and the body.

7. The system of claim 1, wherein the body and the cap are an insulating plastic.

8. The system of claim 4, further comprising a gasket that provides a seal between the cap and the flange of the conductive rod.

9. The system of claim 5, wherein the nut is configured to retain the working electrode through a side of a container.

10. A rapid testing system comprising:
the system of claim 1;
a reference electrode;
a counter electrode;
a container including an electrolyte liquid, the system of claim 1, the reference electrode, and the counter electrode being at least partially submerged in the electrolyte liquid.

11. The rapid testing system of claim 10, further comprising:
a signal generator electrically connected to the system of claim 1, the reference electrode, and the counter electrode.

12. The rapid testing system of claim 11, further comprising:
an ammeter connected between the signal generator and the counter electrode, the ammeter being configured to measure and monitor a current; and
a voltmeter connected between the signal generator and the reference electrode, the voltmeter being configured to measure and monitor a voltage.

13. The rapid testing system of claim 10, wherein the counter electrode is uniformly distributed across from the active material.

14. A rapid testing system comprising:
a working electrode including:
a body;
a conductive rod extending beyond a length of the body and including a recess at one end, the recess being configured to retain an active material; and
a mask to seal and prevent the conductive rod from contacting an electrolyte liquid when the active material is submerged in the electrolyte liquid;
a reference electrode; and
a counter electrode, wherein
the working electrode, the reference electrode, and the counter electrode are partially submerged in the electrolyte liquid, and
a signal generator is electrically coupled to the working electrode, the counter electrode, and the reference electrode to generate a signal and measure characteristics of the active material.

15. The rapid testing system of claim 14, further comprising
a computing device communicatively coupled to the signal generator, the computing device being configured to receive measured characteristics of the active material and display on a user interface of the computing device.

16. The rapid testing system of claim 14, further comprising:
a cap removably connected to the body, wherein
the cap includes a hole exposing the cup and exerting a force on the conductive rod to press the conductive rod against a gasket, creating a seal between the conductive rod and the cap.

17. The rapid testing system of claim 16, wherein:
a first end of the body and a second end of the body include external threads,
the cap includes internal threads, and
the cap attaches to the first end of the body via the external threads and the internal threads.

18. The rapid testing system of claim 17, further comprising a nut configured to screw onto external thread of the second end of the body to retain the working electrode to a side of a container containing the electrolyte liquid.

19. The rapid testing system of claim 14, further comprising a cup removable from the working electrode and including a cavity, the cavity being configured to hold the active material, and the cup being configured to contact the conductive rod.

20. The rapid testing system of claim 14, wherein the mask is a sealing tape configure to expose a portion of the active material held in the recess.
